(19) United States
(12) Patent Application Publication
(10) Pub. No.: US 2014/0273516 A1
(43) Pub. Date: Sep. 18, 2014

(54) VBD AND TDDB IMPROVEMENT THRU INTERFACE ENGINEERING

(71) Applicant: Applied Materials, Inc., Santa Clara, CA (US)

(72) Inventors: Li-Qun XIA, Cupertino, CA (US); Weifeng YE, San Jose, CA (US); Xiaojun ZHANG, Santa Clara, CA (US); Mei-yee SHEK, Palo Alto, CA (US); Mihaela BALSEANU, Sunnyvale, CA (US); Victor NGUYEN, Novato, CA (US); Derek R. WITTY, Fremont, CA (US)

(21) Appl. No.: 14/173,538

(22) Filed: Feb. 5, 2014

Related U.S. Application Data
(60) Provisional application No. 61/778,559, filed on Mar. 13, 2013.

(51) Int. Cl. H01L 21/768

(52) U.S. Cl. CPC H01L 21/76825; H01L 21/76822; H01L 21/76826; H01L 2221/1005
USPC 438/765

(57) ABSTRACT

Methods for the repair of damaged low k films are provided. In one embodiment, the method comprises providing a substrate having a low k dielectric film deposited thereon, and exposing a surface of the low k dielectric film to an activated carbon-containing precursor gas to form a conformal carbon-containing film on the surface of the low k dielectric film, wherein the carbon-containing precursor gas has at least one or more Si—N—Si linkages in the molecular structure.

### CROSS-REFERENCE TO RELATED APPLICATIONS

This application claims benefit of U.S. provisional patent application Ser. No. 61/778,559, filed Mar. 13, 2013 which is herein incorporated by reference.

### BACKGROUND

1. Field

Embodiments of the present invention generally relate to methods for improving the breakdown strength of a barrier/ultra low k dielectric film stack for semiconductor fabrication.

2. Description of the Related Art

Integrated circuits have evolved into complex devices that can include millions of components (e.g., transistors, capacitors and resistors) on a single chip. The evolution of chip designs continually requires faster circuitry and greater circuit densities. The demand for greater circuit densities necessitates a reduction in the dimensions of the integrated circuit components.

As the dimensions of the integrated circuit components are reduced (e.g., sub-micron dimensions), the materials used to fabricate such components contribute to the electrical performance of such components. For example, low resistivity metal interconnects (e.g., aluminum and copper) provide conductive paths between the components on integrated circuits. One method for forming vertical and horizontal interconnects is by a damascene or dual damascene method. In the damascene method, one or more dielectric materials, such as the low k dielectric materials, are deposited and pattern etched to form the vertical interconnects, i.e. vias. These vertical interconnects are typically filled with conductive materials, such as copper containing materials. The substrate is then subjected to an appropriate process to remove CMP residues and metal oxides from the filled conductive materials. A barrier layer is then deposit on the surface of the filled conductive materials to eliminate inter-level diffusion between the filled conductive materials and the surrounding low k films, e.g., ultra low-k interlayer dielectrics (ULK ILD).

Current techniques for the removal of copper oxides (CuO) and chemical mechanical planarization (CMP) residues prior to forming the barrier layer involve the use of ammonia (NH₃) plasmas. Removal of the copper oxides and CMP residues are necessary to improve the electromigration (EM) of the metallization structures and the time dependent dielectric breakdown (TDDB) of the ILD films. However, exposing low k films to NH₃ plasmas leads to carbon removal from the ULK ILD, leaving the surface oxygen rich and susceptible to moisture absorption. Therefore, the k value of the dielectric film is increased. Deposition of barrier layer on damaged ULK ILD also leads to voltage breakdown (Vbd) and TDDB degradation due to unsaturated bonds and moisture penetration through the barrier layer, which is particularly true for dielectric copper barrier having a thinner thickness less than about 150 Å.

Thus, a method for improving the dielectric breakdown strength of the barrier layer/ULK ILD film stack is necessary to insure good performance even when the barrier layer has a thickness below 50 Å.

### SUMMARY OF THE INVENTION

Embodiments of the present invention generally relate to methods for repairing low k films for semiconductor fabrication. In one embodiment, the method comprises providing a substrate having a low k dielectric film deposited thereon, and exposing a surface of the low k dielectric film to an activated carbon-containing precursor gas to form a conformal carbon-containing film on the surface of the low k dielectric film, wherein the carbon-containing precursor gas has at least one or more Si—N—Si linkages in the molecular structure.

In another embodiment, the method comprises subjecting a surface of a low k dielectric film to a plasma generated from a carbon-containing precursor gas comprising an aminosilane to form a conformal carbon-containing film on the surface of the low k dielectric film. The aminosilane may be, for example, hexamethylcyclotrisilazane (HMCTZ) or bis-diethylamine silane (BDEAS).

In either embodiments, the method may further include depositing a first barrier layer on the conformal carbon-containing film, depositing a second barrier layer on the first barrier layer, wherein each of the first barrier layer and the second barrier layer has a band gap different from that of the low k dielectric film to create misalignment of band diagrams associated with the first and second barrier layers at the interface between layers. In one example, the first barrier layer may be subjected to a plasma treatment using argon, a nitrogen source, or in combination, to improve hermiticity of the first barrier layer.

Various aspects of the invention are further discussed in the detailed description below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1E illustrate schematic cross-sectional views of a device structure during various stages of a process flow diagram shown in FIG. 2.

FIG. 2 is a process flow diagram illustrating a method according to one embodiment described herein for repairing an ultra low k dielectric surface.

FIG. 3 is a graph demonstrating dielectric breakdown voltage measured at different electric fields for a damaged ILD and ILD treated with a repairing process before the barrier layer deposition according to one embodiment.

FIG. 4 illustrates an exemplary barrier film stack that may be used to replace the barrier layer of FIG. 1E according to one embodiment.

FIG. 5 is a graph demonstrating dielectric breakdown voltage measured at different electric fields for an ILD with a single barrier and an ILD with a barrier film stack.

FIG. 6 is a graph demonstrating deposited SiN barrier layer's stress change (MPa) measured with different barrier thickness (Å).

### DETAILED DESCRIPTION

Embodiments of the present invention generally provide various methods for improving dielectric breakdown strength of a barrier layer/ILD film stack. While the following description details a repairing process for an ultra low k dielectric (ILD) and the use of a novel barrier structure to improve dielectric breakdown strength of a barrier layer/ILD film stack for a device structure, the embodiments described herein should not be construed or limited to the illustrated examples, as the embodiments may equally applicable to other structures or deposition processes involving a barrier or dielectric film.

### Exemplary Repairing Process

FIGS. 1A-1E illustrate schematic cross-sectional views of a device structure 100 during various stages of a process flow diagram shown in FIG. 2. FIG. 2 is a process flow diagram illustrating a method 200 according to one embodiment described herein for repairing an ultra low k dielectric surface. It should be noted that the number and sequence of process steps illustrated in FIG. 2 are not intended to limiting as to the scope of the invention described herein, since one or more steps may be added, deleted and/or reordered without deviating from the basic scope of the invention.

The method 200 starts at step 202 by providing a substrate 101 into a processing chamber. The term “substrate” as used herein refers to objects that can be formed from any material that has some natural electrical conducting ability or a material that can be modified to provide the ability to conduct electricity. An example of the processing chamber may be a dual or twin chamber on a PRODUCER® system, available from Applied Materials, Inc. of Santa Clara, Calif. Generally, the twin chamber has two isolated processing regions (for processing two substrates, one substrate per processing region) such that the flow rates experienced in each region are approximately one half of the flow rates into the whole chamber. The flow rates described in the examples below and throughout the specification are the flow rates per 300 mm substrate. A chamber having two isolated processing regions is further described in U.S. Pat. No. 5,855,681, which is incorporated herein by reference to the extent not inconsistent with the claimed aspects and disclosure herein. Another example of a processing chamber that may be used is a DxZ® chamber on a CENTURA® system, both of which are available from Applied Materials, Inc.

At step 204, an interlayer dielectric (ILD) 102 is deposited on the surface of the substrate 101, as shown in FIG. 1A, using a suitable deposition technique such as chemical vapor deposition process, followed by UV treatment. The interlayer dielectric 102 may be formed from a low-k material such as a silicon carbide oxide material or a carbon doped silicon oxide material, for example, BLACK DIAMOND® II low-k dielectric material, available from Applied Materials, Inc., located in Santa Clara, Calif. The interlayer dielectric 102 may have a k value of 3 or less, such as 2.5 or less.

At step 206, the interlayer dielectric 102 is pattern etched using any conventional photolithography and etch processes to form metallization features 107 therein, as shown in FIG. 1B. The metallization features 107 define openings of contacts or vias for electrical interconnections used in the semiconductor chip.

At step 208, a metal barrier layer 111, as shown in FIG. 1B, is deposited conformally in the metallization features 107 to prevent migration of subsequently deposited copper into the surrounding interlayer dielectric 102. The metal barrier layer 111 may be formed from titanium, titanium nitride, tantalum, tantalum nitride, tungsten, tungsten nitride, silicides thereof, derivatives thereof, or combinations thereof using any conventional deposition process.

At step 210, the metaillization features 107 are filled with a conductive material 113 using techniques such as chemical vapor deposition, physical vapor deposition, electroplating, or combinations thereof to form the conductive structure, as shown in FIG. 1C. The conductive material may be copper, aluminum, tungsten or combinations thereof. Presently, the trend is to use copper to form the smaller features due to the low resistivity of copper (1.7 mΩ-cm compared to 3.1 mΩ-cm for aluminum).

In cases where copper material is used to fill metaillization features 107, excess copper material (not shown) may be deposited outside the metaillization features 107 of the interlayer dielectric 102. To remove the excess copper material, and to make the thickness of the device structure 100 even, a chemical mechanical polishing (CMP) process may be used. The CMP process may cause copper oxide (CuO) 115 (FIG. 1C) to form on an upper surface of the copper material. The CMP process may also leave residues (not shown) on the surface of the device structure 100, such as, for example, carbon containing compounds from a CMP slurry. As indicated above, removal of the copper oxide 115 and CMP residues using NH₃ plasmas, for example, leads to a damaged ULK ILD (i.e., interlayer dielectric 102) with the surface that is oxygen rich and susceptible to moisture absorption, which in turn causes the k value of the dielectric film to increase.

At step 212, an ULK ILD repairing process is performed by exposing the substrate 101, particularly the damaged ILD surface 116, to an activated carbon-containing organosilicon precursor. Exposing the damaged ILD surface to the activated carbon-containing organosilicon precursor forms a carbon-containing layer thereon, which adds carbon back into the damaged surface of the interlayer dielectric 102 to compensate for the loss of carbon during prior processes as discussed in the background. In general, carbon-containing organosilicon precursors with larger molecule structure and having at least one or more Si—N—Si linkages in the molecular structure are advantageous for repairing and sealing of the damaged ILD surface 116 due to the loss of carbon caused by NH₃ plasmas. Carbon-containing organosilicon precursors with low Si—H concentration are also preferred. The weak binding ability of the Si—H bonds would cause dangling bonds, i.e., unterminated chemical bonds to present on the ILD surface. The dangling bonds manifest as trap sites, which increase the leakage current and degrade breakdown strength of the barrier layer/ILD film stack.

The carbon-containing organosilicon precursor may be activated by an in situ plasma generation process or a remote plasma process, and energized by UV, microwave, RF, electron synchrotron radiation, or any combination thereof. The plasma environment creates long chain radicals with few reaction sites from the carbon-containing organosilicon precursor such that the radicals on the damaged surface can only be cross-linked in certain configurations and numbers to form the Si—N—Si network under these self-limiting reactions. By bringing the surface of the interlayer dielectric 102 into contact with the carbon-containing organosilicon precursor, a conformal carbon-containing film 117 is formed at least on the damaged ILD surface 116 as shown in FIG. 1D. Due to the use of the carbon-containing organosilicon precursor having Si—N—Si linkages, the deposited carbon-containing film 117 will be formed of Si—N—Si bonds with reduced Si—H content at the interface (between ILD and carbon-containing film 117) while putting carbons back into the damaged ILD surface 116.

In one example, the carbon-containing film 117 may have a thickness between about 1 Å and about 100 Å, for example between about 2 Å and about 30 Å, such as 15 Å to 20 Å. In most cases, the carbon-containing film 117 may have a thickness less than 50 Å.

Exemplary carbon-containing organosilicon precursor may include aminosilanes which contain both silicon (Si—) and nitrogen (N—) atoms, substituted with carbon groups such as methyl (—CH₃) or ethyl (—C₂H₅). In one embodiment, the carbon-containing organosilicon precursor may include hexamethylcyclotrisilazane (HMCTZ) or bis(diethylamine)silane (BDEAS). Other carbon-containing organosilicon precursors such as hexamethyidisilazane (HMDS), BTBAS (bis(tertiary butyl-amino)silane), tri(dimethylamino)silane (3DMAS), tetra(dimethylamino)silane (4DMAS), bis(dimethylamino)silane (BDMAS), tris(dimethylamino)chlorosilane, trisilylamine (TSA), silatrane, or the like may also be used.

During the deposition, the damaged ILD surface 116 is exposed to a plasma formed by activating a carbon-containing organosilicon precursor in-situ using a plasma capable deposition chamber, such as a PECVD chamber. In one example where the plasma is generated in-situ by a RF generator, the processing chamber may be pressurized during the repairing process at a pressure of about 0.1 Torr to about 20 Torr, such as from about 1 Torr to about 10 Torr. The chamber or the substrate may be heated to a temperature between about 100° C. and about 450° C., such as from about 150° C. to about 350° C. A gas distributor, or “showerhead”, may be positioned between about 200 mils and about 2000 mils, for example between about 400 mils and about 650 mils from the substrate surface. The carbon-containing organosilicon precursor may be introduced into the chamber at a flow rate between about 1200 mg/min and about 3200 mg/min, for example, between about 1500 mg/min and about 1900 mg/min, optionally providing an inert gas, such as argon, helium, or a combination thereof, to a processing chamber at a flow rate between about 100 sccm and about 20000 sccm, for example, between about 600 sccm and about 2000 sccm. The plasma may be generated by applying a power density ranging between about 0.01 W/cm² and about 10 W/cm², which is a RF power level of between about 10 W and about 2500 W for a 300 mm substrate, and at a high frequency between 13 MHz and 14 MHz, such as 13.56 MHz. The repairing process may be performed between about 1 second and about 200 seconds, for example, between about 60 second and about 150 seconds for formation of the carbon-containing film 117.

Alternatively, all plasma generation may be performed remotely using a remote plasma source (RPS) system that is external from the processing chamber, with the generated radicals introduced into the chamber for repairing of the damaged ILD surface.

In another embodiment where the plasma is promoted by an UV radiation, the UV radiation may be adjusted to contain specific wavelengths which are absorbent by the particular carbon-containing organosilicon precursor being used. The UV radiation may have wavelengths between 10 nm and 400 nm, for example between 190 nm and 365 nm. Useful UV irradiance power density may be between 1000 W/m² and 2000 W/m². The processing chamber may also be heated to a temperature beneficial to the decomposition of the carbon-containing organosilicon precursor.

Table 1 illustrates an exemplary embodiment of using HMCTZ for depositing a carbon-containing film on a 300 mm diameter substrate.

TABLE 1

| | |
|---|---|
| Substrate temperature (° C.) | 200 |
| Pressure (Torr) | 4 |
| RF power (W) | 30 |
| Spacing (mil) | 550 |
| Deposition time (second) | 100 |
| He (sccm) | 200 |
| Ar (sccm) | 800 |
| HMCTZ (mg/min) | 1700 |

In certain embodiments, once the carbon-containing film 117 has been formed using the process conditions discussed herein, the carbon-containing film 117 can be further treated with a plasma treatment, for example by a hydrogen plasma. In such a case, the process may be performed in accordance with Table 1 for about 15 seconds, and followed by the process described in Table 2 below. A carbon-containing film with a thickness of about 3 Å may be obtained after this deposition/plasma treatment process. The deposition/plasma treatment process can be repeated for a number of times, for example 3 or 5 times, until a desired thickness of the carbon-containing film 117 is achieved. In one example, a carbon-containing film with a final thickness of about 15 Å is obtained after the deposition/plasma cyclical process. Table 2 illustrates an exemplary process conditions for a plasma treatment that can be used in forming the carbon-containing film.

TABLE 2

| | |
|---|---|
| Pressure (Torr) | 6 |
| RF power (W) | 250 |
| Spacing (mil) | 550 |
| Processing time (second) | 15 |
| H₂ (sccm) | 500 |

Table 3 illustrates another exemplary embodiment of using BDEAS for depositing a carbon-containing film on a 300 mm diameter substrate.

TABLE 3

| | |
|---|---|
| Substrate temperature (° C.) | 200 |
| Pressure (Torr) | 4 |
| RF power (W) | 30 |
| Spacing (mil) | 350 |
| Deposition time (second) | 10 |
| He (sccm) | 2000 |
| Ar (sccm) | 400 |
| HMCTZ (mg/min) | 1600 |

In certain embodiments, once the carbon-containing film 117 has been formed using the process conditions discussed herein, the carbon-containing film 117 can be further treated with an oxygen-containing gas, for example by an ozone. In such a case, the process may be performed in accordance with Table 3 for about 10 seconds, and followed by the process described in Table 4 below. A carbon-containing film with a thickness of about 0.6 Å may be obtained after this deposition/plasma treatment process. The deposition/plasma treatment process can be repeated for a number of times, for example about 40 times to about 60 times, until a desired thickness of the carbon-containing film 117 is achieved. In one example, a carbon-containing film with a final thickness of about 30 Å is obtained after the deposition/plasma cyclical process. Table 4 illustrates an exemplary process conditions for an ozone treatment that can be used in forming the carbon-containing film.

TABLE 4

| | |
|---|---|
| Pressure (Torr) | 10 |
| Spacing (mil) | 350 |
| Processing time (second) | 10 |
| O₃ (sccm) | 5000 |

FIG. 3 is a graph demonstrating dielectric breakdown voltage measured at different electric fields between 0.0 MV/cm and 4.0 MV/cm (megavolts per centimeter) for a damaged ILD (represented by line “A”) and ILD repaired with the process discussed herein before the barrier layer deposition. The y-axis of FIG. 3 represents current density (A/cm²) and the x-axis represents electric field (MV/cm). The graph shows that repairing damaged dielectric film with UV exposure (represented by line “B”) or plasma activation (represented by line “C”) as shown in Tables 1-4 demonstrates significant improvement in leakage current for a dielectric film (k value of 2.2) over damaged dielectric film not subjecting to repairing process.

At step 214, after the interlayer dielectric 102 has been repaired, a barrier layer 121, as shown in FIG. 1E, is deposited on the surface of the substrate 101 using any conventional deposition process to eliminate inter-level diffusion between the copper and subsequently deposited materials. The barrier layer 121 may be formed from, for example, SiN, SiCN, SiO, SiON, SiOC, SiOCH, or other suitable dielectric materials. The barrier layer 121 may have a thickness between about 10 Å and about 200 Å, for example between about 2 Å and about 100 Å. In one example, the barrier layer 121 is less than 50 Å. In any cases, the barrier layer 121 should have a thickness that does not break down upon application of a voltage.

After the barrier layer 121 has been formed, subsequent processes may be performed to continue the fabrication of the semiconductor device.

### Hermetic Barrier Layer

In addition to repairing the damaged ILD surface, Vbd and TDDB improvement may also be achieved by improving the hermiticity of a barrier layer, for example the barrier layer 121 of FIG. 1E. A hermetic barrier layer is advantageous since it can prevent the moisture from penetrating through the barrier layer to the underlying ILD, which causes the k value of the dielectric film to increase. In one embodiment, a hermetic barrier layer may be obtained through a post plasma treatment using argon or a nitrogen source, or in combination. The nitrogen source for the nitrogen containing plasma may be nitrogen (N₂), NH₃, N₂O, NO₂, or combinations thereof. The plasma may further comprise an inert gas, such as helium, argon, or combinations thereof. In cases where the barrier layer uses SiN, hermiticity improvement can be achieved by subjecting the deposited barrier layer to a nitrogen containing plasma. The post plasma treatment densifies the barrier layer 121 to make the barrier layer hermetic. A hermetic barrier layer may have at least compressive stress of about 20 MPa. The densified barrier layer is also a better barrier since the denser film prevents the diffusion of the conductive material, such as copper, through the barrier layer to subsequently deposited materials. The post plasma treatment may also modify the surface of the barrier layer and the interface between an interlayer dielectric (e.g., interlayer dielectric 102) and the barrier layer, by converting the Si—H bonds into SiN bonds. The Si—H bonds may present at the surface of the barrier layer and/or at the top surface of the interlayer dielectric (due to removal of copper oxides). Si—H bonds, as discussed above, are known to be the leakage path for damaged ILD surface.

During the deposition of the barrier layer, the substrate is exposed to a plasma formed by activating a silicon-containing precursor and a nitrogen-containing precursor in-situ using a plasma capable deposition chamber, such as a PECVD chamber. The barrier layer deposition may be performed in the same chamber as the ULK ILD repairing process or in an adjacent chamber connected to the chamber performing ULK ILD repairing process by a transfer chamber under vacuum.

In one example where the plasma is generated in-situ by a RF generator, the processing chamber may be pressurized during the deposition process at a pressure of about 0.1 Torr to about 20 Torr, such as from about 2 Torr to about 12 Torr. The chamber or the substrate may be heated to a temperature between about 100° C. and about 500° C., such as from about 250° C. to about 400° C. A gas distributor, or “showerhead”, may be positioned between about 150 mils and about 600 mils, for example between about 200 mils and about 400 mils from the substrate surface. The silicon-containing precursor may be introduced into the chamber at a flow rate between about 10 sccm and about 150 sccm, for example, between about 30 sccm and about 50 sccm. The nitrogen-containing precursor may be introduced into the chamber at a flow rate between about 500 sccm and about 2000 sccm, for example between about 700 sccm and about 1200 sccm. A carrier gas, such as nitrogen, is also introduced into a processing chamber at a flow rate between about 600 sccm and about 2000 sccm, for example, between about 800 sccm and about 1400 sccm. The plasma may be generated by applying a power density ranging between about 0.01 W/cm² and about 10 W/cm², which is a RF power level of between about 10 W and about 2500 W for a 300 mm substrate, and at a high frequency between 13 MHz and 14 MHz, such as 13.56 MHz. The deposition may be performed between about 0.1 second and about 10 seconds, for example, between about 1 second and about 5 seconds for formation of the barrier layer such as SiN. The deposited barrier layer may have a thickness of about 10 Å to about 50 Å, for example about 20 Å.

During the post plasma treatment, the deposited barrier layer is subjected to a plasma formed from Ar or nitrogen, or the both. The processing chamber may be pressurized at a pressure of about 0.1 Torr to about 20 Torr, such as from about 2 Torr to about 12 Torr. Argon may be introduced into the chamber at a flow rate between about 6000 sccm and about 20000 sccm, for example, between about 8000 sccm and about 12000 sccm. The nitrogen source may be introduced into the chamber at a flow rate between about 6000 sccm and about 20000 sccm, for example between about 8000 sccm and about 12000 sccm. The plasma may be generated by applying a power density ranging between about 0.01 W/cm² and about 10 W/cm², which is a RF power level of between about 10 W and about 2500 W for a 300 mm substrate, and at a high frequency between 13 MHz and 14 MHz, such as 13.56 MHz. In one example, the RF power level is about 60 W to about 100 W. The post plasma treatment may be performed between about 10 seconds and about 30 seconds, for example, between about 15 seconds and about 25 seconds.

This deposition-plasma treatment can be performed for a desired number of times, such as 3 times, until a desired thickness is reached. The treated barrier layer with desired hermiticity may have a thickness of about 40 Å to about 80 Å, for example about 60 Å.

Table 5 illustrates an exemplary embodiment of using SiH₄ and NH₃ for depositing a SiN barrier layer on a 300 mm diameter substrate.

TABLE 5

| | |
|---|---|
| Substrate temperature (° C.) | 350 |
| Pressure (Torr) | 8 |
| RF power (W) | 75 |
| Spacing (mil) | 300 |
| Deposition time (second) | 3 |
| SiH₄ (sccm) | 40 |
| NH₃ (sccm) | 900 |
| N₂ (mg/min) | 1000 |

Table 6 illustrates an exemplary process conditions for a post plasma treatment that can be used in forming a hermetic barrier layer. While both Ar and N₂ are listed, it is contemplated that the plasma can be formed from either of them or both sources.

TABLE 6

| | |
|---|---|
| Pressure (Torr) | 6 |
| RF power (W) | 440 |
| Processing time (second) | 20 |
| Ar (sccm) | 10000 |
| N₂ (sccm) | 10000 |

FIG. 6 is a graph demonstrating deposited SiN barrier layer's stress change (MPa) measured with different barrier thickness (Å), when the hermetic SiN barrier layer was formed by the processes described in Tables 5 and 6 and then exposed to an atmosphere having about 85 percent humidity at 85 degrees Celsius for 1 day. The graph shows deposited SiN barriers with a thickness greater than about 60 Å meet the required hermiticity threshold of 20 MPa for a Cu barrier layer, and the deposited SiN barrier layer's stress change less than 20 MPa.

In certain embodiments where the barrier layer uses SiCN, hermiticity improvement may be achieved by using an organosilicon precursor containing a Si—N—C backbone, which leads to a more ordered SiCN structure during deposition of the barrier layer 121. Exemplary organosilicon precursors containing a Si—N—C backbone may include, but are not limited to organosilicon precursors having a Si—N—C bond such as bis(alkylamino)dialkoxysilane, bis(cycloalkylamino)dialkoxysilane, alkyl(alkylamino)dialkoxysilane, dialkylaminotrialkoxysilane, and cycloalkylaminotrialkoxysilane. Alternatively, the SiCN barrier layer may be deposited using a mixture of a nitrogen-containing gas and organosilicon precursors such as ethylsilane (CH₃SiH₃), trimethylsilane (TMS), derivatives thereof, and combinations thereof, followed by a post plasma treatment as discussed above.

### Barrier Layer Stack

FIG. 4 illustrates an exemplary barrier film stack 400 that may be used to replace the barrier layer 121 as shown in FIG. 1E. Instead of using a single hermetic barrier layer as discussed above, Vbd and TDDB improvement can also be achieved by using a barrier film stack containing two or more dielectric materials. In one embodiment as shown, the barrier film stack 400 includes a first dielectric layer 402 and a second dielectric layer 404 vertically stacked on an interlayer dielectric 406, for example the interlayer dielectric 102 as shown in FIGS. 1A-1E. Each of the first dielectric layer 402 and the second dielectric layer 404 in the film stack 400 may have a different band gap from that of the interlayer dielectric 406. The variation of the band gap and misalignment of band diagrams associated with different dielectric layers at the interface (created by different dielectric layers) introduce an abrupt step for the breakdown voltage, resulting in improved breakdown strength.

The first dielectric layer 402 and the second dielectric layer 404 may be formed from SiC, SiN, SiO, SiCN, SiON, SiOC, SiOCN, or the like. The interlayer dielectric 406, the first dielectric layer 402 and the second dielectric layer 404 may be different from each other and may be selected from any of the dielectric materials described herein or from any suitable dielectric material known in the art such that the breakdown strength at the interface region is more significant than that of each individual dielectric layer. While any suitable dielectric material may be used, some possible arrangements may include, but are not limited to SiC/SiO/SiN, SiO/SiC/SiN, SiC/SiN/SiO, SiCN/SiO/SiN, SiO/SiCN/SiN, SiCN/SiN/SiO, SiOC/SiO/SiN, SiO/SiOC/SiN, SiOC/SiN/SiO, etc. It is contemplated that the first dielectric layer 402 and the second dielectric layer 404 in the film stack 400 may have a thickness different from each other. In any cases, the overall thickness of the barrier film stack 400 may be less than about 100 Å, such as less than about 50 Å, for example, less than about 20 Å.

FIG. 5 is a graph demonstrating dielectric breakdown voltage measured at different electric fields between 0 MV/cm and 10 MV/cm (megavolts per centimeter) for an ILD (i.e., interlayer dielectric) with a single barrier and an ILD with a barrier film stack using one of the arrangement discussed above such as SiC/SiO/SiN. The y-axis of FIG. 5 represents current density (A/cm²) and the x-axis represents electric field (MV/cm). The graph shows that ILD with the barrier film stack (represented by line “A”) demonstrates significant improvement in leakage current over ILD with a single barrier (represented by line “B”).

While the foregoing is directed to embodiments of the present invention, other and further embodiments of the invention may be devised without departing from the basic scope thereof, and the scope thereof is determined by the claims that follow.

1. A method of processing a low k dielectric film, comprising:
supporting in a processing chamber a substrate having a low k dielectric film deposited thereon; and
exposing a surface of a low k dielectric film formed over a substrate to an activated carbon-containing precursor gas to form a conformal carbon-containing film on the surface of the low k dielectric film, wherein the carbon-containing precursor gas has one or more Si—N—Si linkages in the molecular structure.

2. The method of claim 1, wherein the carbon-containing precursor gas is activated by an in-situ plasma source, a remote plasma source, a UV radiation, or any combination thereof.

3. The method of claim 1, wherein the carbon-containing precursor gas has low Si—H concentration.

4. The method of claim 1, wherein the carbon-containing film comprises Si—N—Si bonds.

5. The method of claim 1, wherein the carbon-containing precursor gas comprises an aminosilane.

6. (canceled)

7. The method of claim 5, wherein the aminosilane is hexamethylcyclotrisilazane (HMCTZ) or bis-diethylamine silane (BDEAS).

8. (canceled)

9. The method of claim 1, further comprising:
depositing a first barrier layer on the conformal carbon-containing film.

10. The method of claim 9, further comprising:
depositing a second barrier layer on the first barrier layer, wherein each of the first barrier layer and the second barrier layer has a band gap different from that of the low k dielectric film to create misalignment of band diagrams associated with the first and second barrier layers at the interface between layers.

11. The method of claim 10, wherein the first barrier layer, the second barrier layer, and the low k dielectric film comprise SiN, SiCN, SiC, SiO, SiON, SiOC, or SiOCH.

12. The method of claim 1, further comprising:
subjecting the carbon-containing film to a hydrogen plasma.

13-14. (canceled)

15. The method of claim 9, wherein the first barrier layer is hermetic having a compressive stress of about 20 MPa.

16. The method of claim 9, wherein the first barrier layer has a thickness less than 80 Å.

17. A method of processing a damaged low k dielectric film, comprising:
subjecting a surface of a low k dielectric film to a plasma generated from a carbon-containing precursor gas comprising aminosilane to form a conformal carbon-containing film on the surface of the low k dielectric film.

18. The method of claim 17, wherein the aminosilane comprises hexamethylcyclotrisilazane (HMCTZ) or bis-diethylamine silane (BDEAS).

19. The method of claim 17, further comprising:
depositing a first barrier layer on the conformal carbon-containing film; and
subjecting the first barrier layer to a plasma treatment in the nitrogen environment.

20. The method of claim 19, further comprising:
depositing a second barrier layer on the first barrier layer, wherein each of the first barrier layer and the second barrier layer has a band gap different from that of the low k dielectric film to create misalignment of band diagrams associated with the first and second barrier layers at the interface between layers.

21. A method of processing a low k dielectric film, comprising:
exposing a surface of a low k dielectric film formed over a substrate to a plasma formed from a carbon-containing precursor gas to form a conformal carbon-containing film on the surface of the low k dielectric film, wherein the carbon-containing precursor gas has one or more Si—N—Si linkages in the molecular structure; and
exposing the substrate to a plasma formed from a silicon-containing precursor to form a barrier layer onto the conformal carbon-containing film.

22. The method of claim 21, wherein the substrate is further exposed to a plasma formed from a nitrogen-containing precursor during formation of the barrier layer.

23. The method of claim 21, wherein the barrier has a compressive stress of about 20 MPa.

24. The method of claim 21, wherein the carbon-containing precursor gas comprises aminosilanes.
